(19) United States
(12) Patent Application Publication
(10) Pub. No.: US 2008/0251117 A1
(43) Pub. Date: Oct. 16, 2008

(54) Solar Cell

(76) Inventors: Markus Schubert, Tubingen (DE); Uwe Rau, Tubingen (DE); Philipp Johannes Rostan, Konstanz (DE); Viet Xuan Nguyen, Narvik (NO)

Correspondence Address: COLLARD & ROE, P.C., 1077 NORTHERN BOULEVARD, ROSLYN, NY, 11576, US

(21) Appl. No.: 11/886,195

(22) PCT Filed: Feb. 25, 2006
(86) PCT No.: PCT/EP2006/001752

§ 371 Date: Sep. 24, 2007

(30) Foreign Application Priority Data
Mar. 14, 2005 (DE) 10 2005 013 668.0

(51) Int. Cl. H01L 31/00

(52) U.S. Cl. 136/255

(57) ABSTRACT

The invention relates to a solar cell with a base layer (12) having a first doping that, together with a front layer (14) having a second doping of opposite polarity, forms a boundary layer. The solar cell has at least one front contact (18) and at least one rear contact (32). A passivation layer (24) and a tunnel contact layer (26, 28) are placed between the base layer (12) and the rear contact (32).

The invention relates to a solar cell, in particular to a solar cell with improved back contact in order to achieve greater efficiency.

In solar cell technology, efforts continue to achieve particularly great efficiencies at the lowest possible cost.

While in the laboratory, depending on the substrate material used, efficiencies exceeding 20% can at times be achieved, typical efficiencies of commercially available solar modules are clearly significantly below 20%.

To achieve the best possible efficiencies, monocrystalline silicon is used as a base material, which is to be used so as to be as thin as possible in order to reduce costs. In this context, placement of the back contacts always poses a problem.

For example, if the back contacts are designed as a continuous metal layer, then recombination losses on the metal-semiconductor boundary interface lead to a reduction in efficiency. For this reason, the back contacts are normally designed as point- or line contacts, which are preferably, applied using the screen printing process.

Furthermore, during cooling on thin silicon wafers, back contacts that extend over the entire area generate very considerable mechanical stress, which in turn results in fracture and in more difficult processability.

Moreover, screen printing processes are relatively expensive and require temperatures of at least approximately 400° C. When thin wafers are used, such elevated temperatures are, however, associated with a problem in that said wafers easily fracture during the process so that the production yield is significantly reduced. Special screen printing pastes are a significant cost factor in the production of solar cells, and, moreover, the composition of said screen printing pastes and the reproducibility of contact formation are expensive to control.

From JP 10135497 A (Patent Abstracts of Japan) a solar cell is known in which the base material comprises a p-doped material whose rear comprises a passivation layer of highly doped material p+. A layer of transparent electrically conductive material, for example ITO (indium tin oxide) has been applied to said material, onto which layer the electrodes have been applied as point- or line-shaped electrodes. The transparent electrically conductive layer can be produced with the use of a sputtering method so that the maximum temperature does not exceed 200° C.

In a similarly designed cell, in which the substrate can be a p-doped or n-doped material, the electrically conductive translucent layer of ITO or similar has been applied to both sides of the substrate so as to prevent bending stress that can lead to curvature of the cell (compare Patent Abstract of Japan JP-A-2003197943).

These solar cells are, however, still associated with a problem, in that while with the use of an n-doped substrate good contacting with an electron conductor, for example ITO, is possible, however, with the use of a p-doped base material, contacting poses problems.

On the other hand, in solar cell technology p-doped material is generally used; it is available in large quantities relatively economically.

It is thus the object of the invention to state an improved solar cell in which good back contacting is ensured even with the use of p-doped material. To this effect the solar cell is to be as economical to produce as possible and is to comprise the best possible efficiency.

This object is met by a solar cell with a base layer with a first doping, which with a front layer with a second doping of reverse polarity (emitter) forms an interface, with at least one front contact and at least one back contact, wherein between the base layer and the back contact at least one passivation layer and a tunnel contact layer are arranged.

In this manner the object of the invention is completely met.

Even with the use of a p-doped material as a base material, the use of a tunnel contact layer makes it possible to achieve particularly high-grade contacting to an electron conductor, for example to a metal or to a translucent conductor, for example zinc oxide or ITO.

In a preferred improvement of the invention the passivation layer comprises a doped material of the same polarity as the base layer.

In the solar cell according to the invention it is furthermore possible to design the back contact as a metallic surface contact, without this having a negative effect on efficiency.

For this purpose, in an advantageous improvement of the invention, a transparent electrically conductive layer is provided between the tunnel contact layer and the back contact, which conductive layer preferably comprises zinc oxide, indium tin oxide or a conductive polymer. This layer is also used to improve the reflection at the rear, as a result of which the efficiency is improved.

Particularly preferable is the use of a zinc oxide layer because this is significantly more economical than the use of ITO.

The back contact and, if need be, the front contact can be made of metal, for example of aluminium, or in particularly high-grade applications of gold, silver or some other metal.

The passivation layer preferably comprises amorphous silicon (a-Si).

The tunnel contact layer is preferably made of microcrystalline silicon (μc-Si). It can, for example, comprise a first highly doped layer of the same polarity as the base layer, followed by a second highly doped layer of reversed polarity.

If the base layer is p-doped, the front layer is then n-doped, with the passivation layer preferably being a p-doped layer followed by the tunnel contact layer in the form of a highly doped p+-layer which is followed by a highly doped n+-layer. The n+-layer can then in a simple and reliable manner be contacted to an electronically conductive material, for example ZnO.

In this context the term “highly doped” refers to the layer having higher doping than the base material; in other words the number of doping atoms per unit of volume is, for example, greater by at least one magnitude.

According to an alternative design, it is possible to produce the tunnel contact layer without an n+-layer, with only a first p-layer followed by a second p+-layer, which layers preferably both comprise μc-Si.

According to a further embodiment of the invention, a thin non-doped (intrinsic) layer of a-Si is arranged between the passivation layer and the base layer.

This intrinsic layer serves as a buffer between the wafer and the passivation layer. In combination with it, particularly good passivation results are achieved.

According to a further embodiment of the invention, at least the passivation layer, the tunnel contact layer or the intrinsic layer comprises hydrogen.

This can, for example, be hydrogen at a percentage of between 1 and 20%, which is preferably contained both in the intrinsic layer and in the passivation layer as well as in the tunnel contact layer.

Hydrogen plays a significant role in the passivation of the dangling bonds. Overall, in this way, with suitable hydrogen concentration, efficiency is further improved.

The base material of the solar cell preferably comprises monocrystalline silicon, provided particularly good efficiency is desired.

For more economical solar cells the base material can comprise multicrystalline silicon (mc-Si).

The light-side design of the solar cell can be conceived in any desired manner, as is basically known from the state of the art.

To this effect it is possible, for example, to use metallic front contacts while the light-side surface of the solar cell comprises a reflection-reducing passivation layer, for example SiO₂. It is understood that the passivation layer is interrupted in the region of the front contacts.

In particular, the light-side design of the solar cell, as is basically known from the state of the art, can be designed as a heterojunction, for example comprising an a-Si emitter, at low process temperatures of a maximum of approximately 250° C., preferably a maximum of 200° C.

The layers of the solar cell are preferably applied in the thin-film method, in particular using plasma CVD, sputtering or catalytic CVD (hot wire CVD).

In this way the process temperature during the entire manufacture of the solar cell can be limited to temperatures of a maximum of approximately 250° C., preferably a maximum of 200° C.

In this way, bending, curvature and fracture of the solar cell can be prevented even if a thin substrate material is used.

It is understood that the above-mentioned characteristics of the invention and the characteristics of the invention that are still to be explained below are applicable not only in the respective combinations stated but also in other combinations or on their own, without leaving the scope of the invention.

Further characteristics and advantages of the invention are provided in the following description of a preferred exemplary embodiment with reference to the drawing.

The drawing shows the following:

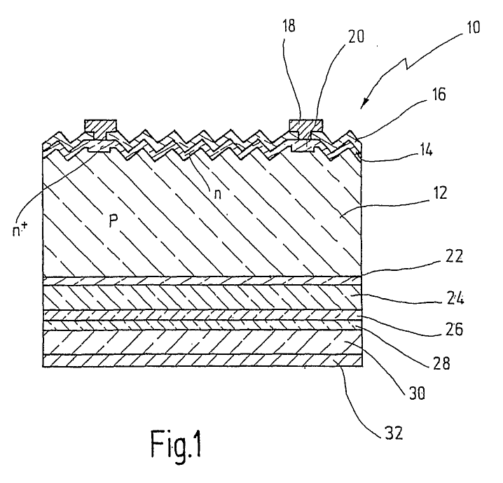

the sole FIG. 1: a simplified view of a partial section of a solar cell according to the invention.

FIG. 1 diagrammatically shows a cross-section of a solar cell according to the invention and is overall designated 10. The solar cell 10 comprises a p-doped base layer 12 of monocrystalline silicon.

On the front that faces the radiation side an n-doped silicon layer 14 has been applied that forms an interface (pn junction) to the base layer 12. The n-doped silicon layer 14 is preferably structured such that reflections are reduced. Contacting on the front by means of front contacts 18 can take place, for example, by means of aluminium contacts, which in each case are preferably contacted over an area 20 with a highly doped n+-layer. Furthermore, the front layer 14 has been passivated by means of a passivation layer 16, which can, for example, comprise SiO₂.

At the rear, the base layer 12 is followed by a thin intrinsic layer 22 comprising amorphous silicon.

The intrinsic layer 22 is followed by a passivation layer 24, which is preferably designed as a p-doped a-Si layer.

This layer 24 is adjoined by a further layer 26 which comprises microcrystalline silicon μc-Si, which layer 26 is highly doped (p+).

This μc-Si layer 26 is adjoined by a further layer 28 of microcrystalline silicon μc-Si, which is also highly doped, but with reverse polarity (n+).

The two layers 26, 28 of μc-Si with p+doping, followed by n+doping, together form a tunnel contact layer.

The n+-doped μc-Si-layer 28 is adjoined by a zinc oxide layer 30, on which the back contact layer 32 has been applied as a continuous metallic layer which can, for example, comprise aluminium.

The layers 22 to 28 preferably comprise hydrogen at a percentage of between 1 and 20%.

This layer design ensures very good contacting of the base layer 12 to an electron conductor, although the base layer 12 is a slightly p-doped layer. This is, in particular, achieved by means of the tunnel contact layer 26, 28, which is formed from the microcrystalline p+ layer followed by the microcrystalline n+ layer. As an alternative, which also returns good results, the tunnel contact layer 26, 28 can comprise a first p-doped a-Si or μc-Si layer, followed by a p+-doped microcrystalline μc-Si layer.

The layer thickness of the only optionally used intrinsic a-Si layer 22 is preferably between approximately 5 and 20 nm, preferably approximately 10 nm. The layer thickness of the passivation layer 24 is preferably between approximately 20 and 60 nm, preferably approximately 40 nm. The layer thickness of the microcrystalline layer 26 is preferably between approximately 5 and 25 nm, in particular approximately 10 nm. The layer thickness of the microcrystalline layer 28 is preferably between approximately 1 and 15 nm, in particular approximately 5 nm.

The layer thickness of the transparent electrically conductive layer of ZnO, ITO or the like is preferably between approximately 20 and 150 nm, in particular between approximately 40 and 120 nm, for example 80 nm.

The back contact layer 32, which for example comprises aluminium, can have a thickness of between approximately 0.5 and 5 μm, for example 1 μm.

The electrically conductive layer 30 made of a material that is transparent (in the wavelength range that is of interest), for example of ZnO, improves the reflection of the back contact layer 32 and thus improves efficiency. In principle, instead of ZnO, some other layer material, for example ITO, could be used, however ZnO is clearly more economical in mass production.

Application of the layers to the base layer takes place by means of a suitable thin-film method, for example plasma enhanced CVD (PECVD), sputtering, hot-wire CVD etc. The preferred hydrogen diffusion within the layers 22 to 28 takes place by means of a subsequent increase in the temperature to approximately 200° C.

In the production of laboratory specimens of a solar cell according to the invention, on the one hand PECVD and on the other hand hot-wire CVD were used. The intrinsic a-Si-layer was deposited in PECVD with silane (SiH₄) and hydrogen at a plasma frequency of 13.56 MHz and a pressure of 200 mTorr and an output of 4 Watt. The doped a-Si layer was produced with silane, hydrogen and boroethane (B₂H₆), alternatively with phosphine (PH₄) at 80 MHz plasma frequency and a pressure of 400 mTorr and an output of 20 watt.

In the case of hot wire depositing, a wire temperature of approximately 1700° C. and a pressure of 100 mTorr is used. All the depositing takes place in high-vacuum- or ultra-high-vacuum facilities.

At the laboratory scale, with a solar cell according to the invention, both with the tunnel contact layer comprising μc-Si p+ followed by μc-Si n+, and with the use of the alternative tunnel contacting with μc-Si p followed by μc-Si p+, it was possible to achieve efficiencies of at least 20%. To this effect only Al-doped ZnO was used as a back contact layer. This did not require any contacting with the significantly more expensive ITO.

A continuous processing plant could be used for industrial production.

Back contacting according to the invention is suitable for all silicon solar cells, irrespective of the type of contacting used at the front.

1. A solar cell with a base layer (12) with a first doping, which with a front layer (14) with a second doping of reverse polarity forms an interface, with at least one front contact (18) and at least one back contact (32), wherein between the base layer (12) and the back contact (32) at least one passivation layer (24) and a tunnel contact layer (26, 28) are arranged;
wherein an intrinsic layer of a-Si is arranged between the passivation layer (24) and the base layer (12).

2. The solar cell according to claim 1, wherein the passivation layer (24) comprises a doped material or a highly doped material of the same polarity as the base layer (12).

3. The solar cell according to claim 1, wherein the back contact (32) is a metallic surface contact.

4. The solar cell according to claim 1, wherein at least one of the back contact (32) and the front contact (18) is made of aluminium, gold, silver or some other metal.

5. The solar cell according to claim 1, wherein the passivation layer (24) comprises amorphous silicon (a-Si).

6. The solar cell according to claim 1, wherein the tunnel contact layer (26, 28) comprises microcrystalline silicon (μc-Si).

7. The solar cell according to claim 1, wherein the tunnel contact layer (26, 28) comprises a first highly doped layer (26) and a second highly doped layer (28) of reversed polarity.

8. The solar cell according to claim 1, wherein the base layer (12) is p-doped, the front layer is n-doped, and the tunnel contact layer (26, 28) comprises a highly doped p+-layer (26) and a highly doped n+-layer (28).

9. The solar cell according to claim 1, wherein the tunnel contact layer comprises a first, doped, layer (26) and a second, highly doped, layer (28) of the same polarity.

10. The solar cell according to claim 1, wherein the base layer (12) is p-doped, the front layer n-doped, and the tunnel contact layer (26, 28) comprises a first p-layer (26) and a second, highly doped, p+-layer (28).

11. The solar cell according to claim 8, wherein the passivation layer (24) is a p-doped layer or a highly doped p+-layer.

12. (canceled)

13. The solar cell according to claim 1, wherein a transparent electrically conductive layer (30) is provided between the tunnel contact layer (26, 28) and the back contact (32), which layer (30) preferably comprises zinc oxide (ZnO), indium tin oxide (ITO) or a conductive polymer.

14. The solar cell according to claim 1, wherein at least the passivation layer (24), the tunnel contact layer (26, 28) or the intrinsic layer (22) comprises hydrogen.

15. The solar cell according to claim 14, wherein at least the passivation layer (24), the tunnel contact layer (26, 28) or the intrinsic layer (22) comprises hydrogen at a percentage of between 1 and 20 at. %.

16. The solar cell according to claim 1, wherein the base material (12) comprises monocrystalline silicon or multicrystalline silicon (mc-Si).

17. The solar cell according to claim 1, wherein the front layer (14) comprises a passivation layer (16) that is interrupted in the region of the front contact (18).

18. The solar cell according to claim 1, wherein at least one of the layers has been produced in a thin-film method, in particular using plasma CVD, sputtering or catalytic CVD (hot wire CVD).

19. The solar cell according to claim 1, wherein the layers have been applied at temperatures of a maximum of approximately 250° C., preferably a maximum of 200° C.
